(19) United States
(12) Patent Application Publication
(10) Pub. No.: US 2004/0012449 A1
(43) Pub. Date: Jan. 22, 2004

(54) Ring oscillator with frequency stabilization

(76) Inventor: Paul F. Illegems, Albuquerque, NM (US)

Correspondence Address: Corporate Patent Counsel, U.S. Philips Corporation, 580 White Plains Road, Tarrytown, NY, 10591, US

(21) Appl. No.: 10/195,949

(22) Filed: Jul. 16, 2002

(51) Int. Cl. H03B 27/00

(52) U.S. Cl. 331/57

(57) ABSTRACT

A current-controlled ring oscillator uses a single controlled-current supply for supplying current to each inversion stage of the ring oscillator. The controlled current is dynamically adjusted to compensate for variations in process, voltage, or temperature conditions. A relatively simple circuit is used to generate the controlled current that supplies all of the inversion stages over a wide range of process, voltage, and temperature variations.

### BACKGROUND OF THE INVENTION

1. Field of the Invention

This invention relates to the field of electronic circuits, and in particular to a ring oscillator that provides a stable frequency over a variety of process, voltage, and temperature conditions.

2. Description of Related Art

Ring oscillators are common in the art, and comprise an odd number of inverters connected in a series-ring configuration. FIG. 1 illustrates an example ring oscillator 100 that has five inverters 110 connected in a ring. A buffer 120 provides the output of the oscillator 100 to a load (not shown) and isolates the ring oscillator 100 from the load. Because there are an odd number of inverters 110 in the ring, each inverter continually switches state. The frequency of oscillation of the oscillator 100 is determined by the speed at which the inverters 110 change state, which is primarily determined by the size of the devices used in the inverters 110. The switching speed is also dependent upon the parameters of the process used for creating the oscillator 100, the operating temperature, and the supply voltage (Vdd-Vss). In a typical span of process parameters (slow, medium, fast), temperature (0-120° C.), and supply voltage (1.6-2.0V), the frequency of oscillation may vary by as much as 40% from nominal.

U.S. Pat. No. 5,331,295, “VOLTAGE CONTROLLED OSCILLATOR WITH EFFICIENT PROCESS COMPENSATION”, issued Jul. 19, 1994 to Jelinek et al., teaches a current-controlled ring-oscillator that provides a controlled oscillation frequency that includes compensation for process, voltage, and temperature variations. FIG. 2 illustrates an example ring oscillator 200 as taught by Jelinek et al. The current to each inverter stage 110 is controlled by current-limiting transistors 210, 215. A current controller 250 controls each of the current-limiting transistors 210. A transistor pair 230, 235 is configured to provide an equal current to the corresponding current-limiting transistors 215.

### BRIEF SUMMARY OF THE INVENTION

It is an object of this invention to provide a simple yet effective means for providing an oscillation frequency that is stable across a variety of process, voltage, and temperature variations. It is a further object of this invention to provide a ring oscillator that is stable across a variety of process, voltage, and temperature variations, that uses very few components to achieve this stability.

These objects, and others, are achieved by a current-controlled ring oscillator that uses a single controlled-current supply, independent of the number of inversion stages within the oscillator. The controlled current is dynamically adjusted to compensate for variations in process, voltage, or temperature conditions. A relatively simple circuit is used to generate the controlled current that supplies all of the inversion stages over a wide range of process, voltage, and temperature variations.

### BRIEF DESCRIPTION OF THE DRAWINGS

The invention is explained in further detail, and by way of example, with reference to the accompanying drawings wherein:

FIG. 1 illustrates an example block diagram of a prior art ring oscillator.

FIG. 2 illustrates an example block diagram of a prior art ring oscillator with process, voltage, and temperature compensation.

FIGS. 3A and 3B illustrate an example block diagram and an example circuit diagram, respectively, of a ring oscillator with process, voltage, and temperature compensation in accordance with this invention.

FIG. 4 illustrates an example circuit diagram of a prior art temperature compensating current source.

Throughout the drawings, the same reference numerals indicate similar or corresponding features or functions.

### DETAILED DESCRIPTION OF THE INVENTION

FIGS. 3A and 3B illustrate an example block diagram and an example circuit diagram, respectively, of a ring oscillator 300 with process, voltage, and temperature compensation in accordance with this invention. A current source 350 provides a substantially constant current that is used to supply the operating current to each of the inverter stages 110 of the ring oscillator 300. This substantially constant current is controlled so as to compensate for voltage, temperature, and process variations, as detailed further below. That is, the controlled current is substantially constant at a current value that is dynamically varied, depending upon the particular set of voltage, temperature, and process conditions.

The switching of each inversion stage 110 comprises a repeated charging and discharging of capacitances within each inversion stage. The prior art ring oscillator 200 of FIG. 2 provides frequency-regulation by controlling the current provided to each inversion stage, thereby controlling the time required to charge and discharge the capacitances of each inversion stage.

The invention of this application is premised on the observation that the inherent symmetry of a ring oscillator produces a relatively constant total current draw, or at least a symmetric and repetitive current draw from period to period. By providing a controlled-current supply to all of the inversion stages 110, the current consumption per period is approximately constant, and therefore the oscillation frequency is constant. Recognizing this inherent symmetry, the need for independent current-control for each stage, as in the prior ring oscillator 200 of FIG. 2, is avoided, thereby providing a less costly and less complex embodiment, as compared to the oscillator 200.

The current source 350 is configured to provide the controlled current over a wide range of process, voltage, and temperature variations, such that the frequency of oscillation of the ring counter is controlled to within a limited variance. As the operating temperature of the ring oscillator increases, the speed of switching decreases, thereby reducing the frequency of oscillation. In a straightforward embodiment, a conventional PTAT (proportional to absolute temperature) current source may be used to provide a current that increases with temperature, to compensate for this frequency reduction. The degree of compensation required can be determined using conventional circuit simulation tools, and/or circuit optimization tools.

In like manner, regarding process parameters, the switching speed varies inversely with the threshold voltage of the transistors in the ring oscillator, and directly with the gain, or beta, of the transistors. Therefore in a preferred embodiment, the current source 350 is also configured to increase the supplied current when the transistor threshold voltage increases, and when the transistor beta decreases.

Also preferably, the current source 350 is configured to provide the aforementioned temperature-compensated and/or process-compensated controlled current substantially independent of the supply voltage. As is common in the art, for example, a bandgap voltage reference, which may be implemented using bipolar or field-effect circuits, typically includes a PTAT current flow in one or more of its branches.

In a preferred embodiment, as illustrated in FIG. 3B, the current source 350 comprises a pair of series connected resistors R1 351, R2 352 that control the current through a series connected transistor 354. The common node between the series connected resistors 351, 352 provides the control voltage at the gate of transistor 354, and the terminal node of the series provides the current through the transistor 354. The terminal node of the series also provides the control voltage at the gate of a transistor 356 that provides the controlled current, i, via a current mirror arrangement 359. The particular values of R1, R2, and the sizes of the transistors 354 and 356 are determined using conventional circuit simulation and optimization techniques so as to provide a relatively constant oscillation frequency over a given set of process, temperature, and voltage conditions. In an example embodiment, the following values provided for less than 10% variation in oscillator frequency over a typical span of process parameters (slow, nominal, fast), temperature (0-120° C.), and supply voltage (1.6-2.0V):

R1=116.7 KΩ;

R2=10.4 KΩ;

T 354: width 4 μm, length 1.06 μm; and

T 356: width 8.42 μm, length 3.2 μm.

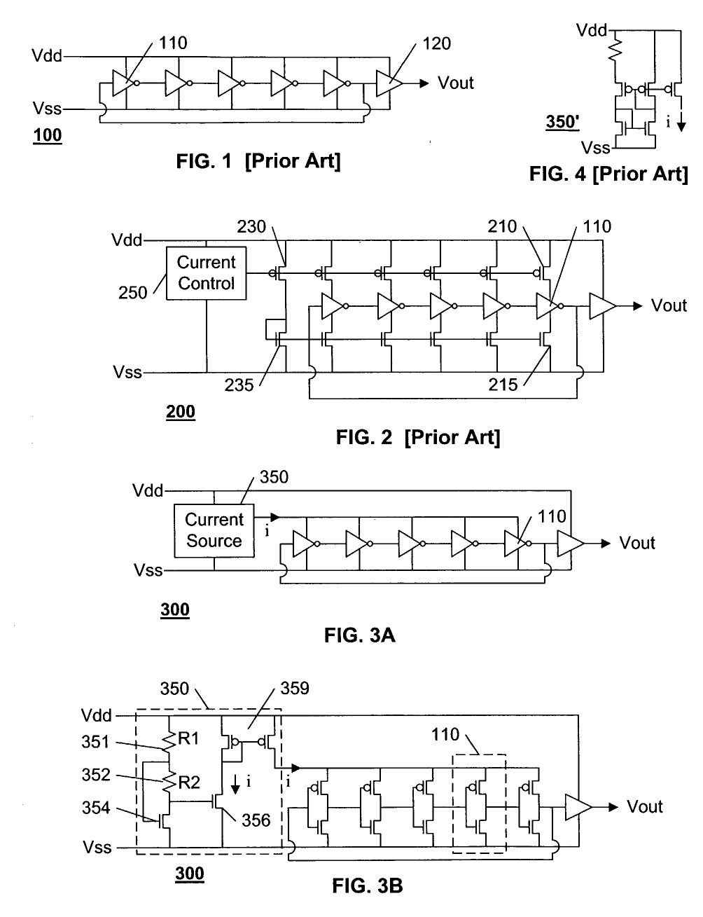

This result compares very favorably to the aforementioned typical 40% variation of the conventional ring oscillator 100 of FIG. 1. Similar results were found using a conventional PTAT current source, such as illustrated as 350′ in FIG. 4.

Although the example circuits of FIG. 3B and FIG. 4 illustrate the use of field-effect transistors, one of ordinary skill in the art will recognize that other technologies, such as bipolar, may also be used to provide the controlled current, i. As noted above, the controlled current, i, preferably:

increases with temperature;

increases with transistor threshold voltage;

decreases with transistor beta; and

remains constant with supply voltage.

The foregoing merely illustrates the principles of the invention. It will thus be appreciated that those skilled in the art will be able to devise various arrangements which, although not explicitly described or shown herein, embody the principles of the invention and are thus within the spirit and scope of the following claims.

I claim:

1. A ring oscillator, comprising:
a current generator that is configured to provide a controlled current output, and
an odd number of inversion stages, operably coupled in a ring configuration, and operably coupled to the current generator,
wherein
the inversion stages are commonly powered by the controlled current output.

2. The ring oscillator of claim 1, wherein
the current generator comprises:
a first resistor operably coupled between a first voltage source and a first node,
a second resistor operably coupled between the first node and a second node,
a first transistor having a gate that controls current flow between a first terminal and a second terminal of the first transistor, and
the gate is operably coupled to the first node,
the first terminal is operably coupled to the second node, and
the second terminal is operably coupled to a second voltage source; and
a second transistor having a gate that controls current flow between a first terminal and a second terminal of the second transistor, and
the gate is operably coupled to the second node,
the first terminal is operably coupled to the second voltage source, and
the second terminal is operably coupled to the controlled current output.

3. The ring oscillator of claim 2, wherein
the current generator further comprises
a current mirror operably coupled between the second terminal of the second transistor and the controlled current output.

4. The ring oscillator of claim 3, wherein
each of the inversion stages include:
a third transistor having a gate that controls current flow between a first terminal and a second terminal of the third transistor, and
the gate is operably coupled to a prior inversion stage,
the first terminal is operably coupled to the controlled current output, and
the second terminal is operably coupled to a next inversion stage; and
a fourth transistor having a gate that controls current flow between a first terminal and a second terminal of the fourth transistor, and
the gate is operably coupled to the prior inversion stage,
the first terminal is operably coupled to the next inversion stage, and
the second terminal is operably coupled to the second voltage source.

5. The ring oscillator of claim 2, wherein
resistance values of the first resistor and the second resistor, and size values of the first transistor and the second transistor are determined so as to provide the controlled current output to produce a substantially constant oscillation frequency over a wide range of process, voltage, and temperature variations.

6. The ring oscillator of claim 1, wherein
the current generator is configured to increase the controlled current output based on at least one of:
an increase in operating temperature,
an increase in threshold voltage, and
a decrease in beta.

7. The ring oscillator of claim 1, wherein
the current generator is configured to provide the controlled current output independent of a variance of a supply voltage to the current generator.

8. The ring oscillator of claim 1, wherein
each of the inversion stages include:
a first transistor having a gate that controls current flow between a first terminal and a second terminal of the first transistor, and
the gate is operably coupled to a prior inversion stage,
the first terminal is operably coupled to the controlled current output, and
the second terminal is operably coupled to a next inversion stage; and
a second transistor having a gate that controls current flow between a first terminal and a second terminal of the second transistor, and
the gate is operably coupled to the prior inversion stage,
the first terminal is operably coupled to the next inversion stage, and
the second terminal is operably coupled to a voltage source.

9. The ring oscillator of claim 1, wherein
the current generator includes a PTAT current generator.

10. A method of controlling an output frequency of a ring oscillator that includes a plurality of inversion stages, comprising:
providing a controlled current, and
supplying the controlled current to each inversion stage of the plurality of inversion stages of the ring oscillator.

11. The method of claim 10, further including
increasing the controlled current based on at least one of:
an increase in operating temperature,
an increase in threshold voltage of the plurality of inversion stages, and
a decrease in beta of the plurality of inversion stages.

12. The method of claim 10, wherein
the controlled current is substantially independent of variances of a voltage source that provides the controlled current.
